(19) United States
(12) Patent Application Publication
(10) Pub. No.: US 2013/0260140 A1
(43) Pub. Date: Oct. 3, 2013

(54) AUXILIARY SHEET FOR LASER DICING

(71) Applicants: Mitsunori Maruyama, Saitama (JP); Nobuyuki Abe, Saitama (JP)

(72) Inventors: Mitsunori Maruyama, Saitama (JP); Nobuyuki Abe, Saitama (JP)

(73) Assignee: KIMOTO CO., LTD., Saitama (JP)

(21) Appl. No.: 13/991,951

(22) PCT Filed: Nov. 16, 2011
(86) PCT No.: PCT/JP2011/076374

§ 371 Date: Jun. 6, 2013

(30) Foreign Application Priority Data
Dec. 6, 2010 (JP) 2010-271026

(51) Int. Cl. H01L 21/683

(52) U.S. Cl. CPC H01L 21/6836
USPC 428/335; 428/345; 428/354; 428/339

(57) ABSTRACT

An auxiliary sheet for laser dicing, which is not cut fully even in a dicing step using a short-wavelength laser and does not deteriorate workability, is provided. The auxiliary sheet for laser dicing of the present invention is characterized by comprising a substrate formed of a polyolefin film and an adhesive layer provided to one surface of the substrate, wherein total light transmittance is 50% or higher in a wavelength range of 300 to 400 nm and haze is 70% or higher in a wavelength range of 300 to 400 nm.

### TECHNICAL FIELD

The present invention relates to an auxiliary sheet for laser dicing used preferably for fixing a semiconductor wafer and an optical device wafer, etc. to a substrate when producing semiconductor chips and optical devices, etc. by dividing the substrate of the semiconductor wafer and optical device wafer, etc. into individual pieces by irradiating a laser light.

### BACKGROUND ART

Among substrates of semiconductor devices and optical device wafers, etc., for example, a semiconductor wafer is, after a circuit is formed on a surface thereof, subjected to a backside grinding step for performing grinding processing on a backside of the semiconductor wafer to adjust a thickness of the semiconductor wafer, and a dicing step for dividing the semiconductor wafer into individual pieces having a predetermined chip size. Also, the backside grinding step may be followed by further etching processing, polishing processing or other processing on the backside or processing performed at a high temperature, such as evaporation of a metal film on the backside, may be performed in some cases.

In the dicing step above, normally an auxiliary sheet for dicing is fixed to the semiconductor wafer (patent document 1). By using the auxiliary sheet for dicing in the step above, chipping on the semiconductor chips and scattering of the chips can be prevented as well as damages on the semiconductor wafer can be suppressed. Such an auxiliary sheet for dicing normally has a configuration wherein an acrylic type adhesive agent, etc. is applied to a substrate layer formed of a plastic film, etc. and dried to form an adhesive layer having a thickness of about 1 to 50 μm.

Dicing of a semiconductor wafer is normally performed by using a rotary circular blade, however, in recent years, dicing using a laser light (laser dicing) has been proposed. According to laser dicing, some work which is hard to cut by blade dicing can be cut in some cases, so that it has attracted attentions. A variety of laser dicing sheets used for such laser dicing have been proposed (patent documents 2 to 3).

### RELATED ART DOCUMENTS

### Patent Documents

Patent Document 1: Japanese Patent Unexamined Publication (Kokai) No. H02-187478
Patent Document 2: Japanese Patent Unexamined Publication (Kokai) No. 2002-343747
Patent Document 3: Japanese Patent Unexamined Publication (Kokai) No. 2005-236082

### SUMMARY OF THE DISCLOSED SUBJECT MATTER

There have been demands for a reduction in size and thickness of semiconductor chips and optical device chips, etc. in recent years. To respond thereto, substrates of semiconductor wafers and optical device wafers, etc. have to be also thinner. When substrates of semiconductor wafers and optical device wafers, etc. are made thinner, it normally results in a decline of the strength. Therefore, to secure that, substrates having higher hardness than before, for example, a sapphire substrate and a substrate obtained by depositing silver on copper have started to be used.

Because these substrates have high hardness as explained above, a dicing capability of a conventionally used laser light is not enough for such substrates. Therefore, to respond thereto, a laser having a short wavelength of 300 to 400 nm or so has become in use in recent years.

Such a short-wavelength laser has high energy density and excellent dicing capability, however, for example, in the case of a semiconductor wafer, not only the semiconductor wafer but a dicing auxiliary tape is cut fully in the dicing step and there arose a disadvantage that workability declines in collecting semiconductor chips.

According to an aspect of the present invention, there is provided an auxiliary sheet for laser dicing, which is not cut fully even in a dicing step using a short-wavelength laser and does not deteriorate workability.

The present inventors have found that it is possible to provide an auxiliary sheet for laser dicing having the capabilities as above by the configuration of using a polyolefin film as a substrate and providing specific optical characteristics and attained the present invention.

Namely, the auxiliary sheet for laser dicing of the present invention is characterized by comprising a substrate and an adhesive layer provided on one surface of the substrate: wherein the substrate is formed of a polyolefin film, total light transmittance is 50% or higher in a wavelength range of 300 to 400 nm, and haze is 70% or higher in a wavelength range of 300 to 400 nm.

Also, preferably, the auxiliary sheet for laser dicing of the present invention is characterized in that the substrate is formed of a single layer of a polypropylene film or a polyethylene film, a plurality of layers of polypropylene films or polyethylene films, or a plurality of layers of a polypropylene film and a polyethylene film.

According to the inventions above, since the auxiliary sheet for dicing comprises a substrate and an adhesive layer provided on one surface of the substrate, wherein the substrate is formed of a polyolefin film, a total light transmittance is 50% or higher in a wavelength range of 300 to 400 nm, and haze is 70% or higher in a wavelength range of 300 to 400 nm; it is not cut fully even in a dicing step using a short-wavelength laser and workability is not deteriorated thereby.

### EXEMPLARY MODE FOR CARRYING OUT THE DISCLOSED SUBJECT MATTER

An auxiliary sheet for laser dicing of the present invention is characterized by comprising a substrate and an adhesive layer provided on one surface of the substrate, wherein the substrate is formed of a polyolefin film, a total light transmittance is 50% or higher in a wavelength range of 300 to 400 nm, and haze is 70% or higher in a wavelength range of 300 to 400 nm. Below, processing work of a semiconductor wafer will be taken as an example to explain an embodiment of the respective components.

Note that “total light transmittance” in the present invention indicates a total light transmittance defined by JIS K7375:2008. Also, “haze” indicates a value calculated from a formula below.

Haze (%)=(diffused light transmittance/total light transmittance)×100

Also, “a total light transmittance in a wavelength range of 300 to 400 nm” indicates an average value of those obtained by measuring total light transmittance at an interval of 1 nm in the wavelength range of 300 to 400 nm. Also, “haze in a wavelength range of 300 to 400 nm” indicates an average value of those obtained by measuring haze at an interval of 1 nm in the wavelength range of 300 to 400 nm.

The auxiliary sheet for laser dicing of the present invention has a total light transmittance of 50% or higher in a wavelength range of 300 to 400 nm. As a result of the total light transmittance of 50% or higher in the range above, it is possible to prevent a short-wavelength laser from staying at the auxiliary sheet for laser dicing and to prevent the auxiliary sheet for laser dicing from fracturing. Total light transmittance in the wavelength range of 300 to 400 nm is preferably 70% or higher and more preferably 80% or higher.

Also, the auxiliary sheet for laser dicing of the present invention has haze of 70% or higher in a wavelength range of 300 to 400 nm. As a result of the haze being 70% or higher, it is possible to diffuse a light when a short-wavelength laser is irradiated to the auxiliary sheet for laser dicing, and it is possible to prevent the auxiliary sheet for laser dicing from fracturing. The haze is preferably 75% or higher and more preferably 80% or higher.

Note that the total light transmittance and haze in the wavelength range of 300 to 400 nm defined in the present invention indicate values when irradiating light from the adhesive layer side of the auxiliary sheet for laser dicing of the present invention. However, they may be those satisfying the values above when irradiating a light from the substrate side, as well.

The substrate is formed of a polyolefin film. Since a polyolefin film has high transmittance of a short-wavelength laser of 300 to 400 nm or so, by using the polyolefin film as an auxiliary sheet for laser dicing, it is possible to prevent being cut fully even when being irradiated with a short-wavelength laser.

As a polyolefin film, a polyethylene film, polypropylene film, polybutene film, polymethylpentene film, an ethylene-propylene copolymer, ethylene-propylene-butene copolymer and other films may be mentioned. Among them, for being excellent for mass production and being low at laser processability, a polyethylene film and polypropylene film are preferably used and, particularly, a polyethylene film is preferably used.

A pigment may be contained in the polyolefin film so as to satisfy total light transmittance and haze specified in the invention of the present application. As such a pigment, organic resin particles formed of a stylene resin, polyethylene resin, urethane resin, benzoguanamine resin, nylon resin, silicon resin and acrylic resin, etc. and inorganic particles, such as silica, barium sulfate, aluminum hydroxide, magnesium hydroxide, calcium carbonate, magnesium carbonate, calcium silicate, magnesium silicate, titanium oxide, calcium oxide, magnesium oxide, aluminum oxide, zirconium oxide, aluminum nitride, aluminum borate whisker and boron nitride, etc. may be mentioned.

A polyolefin film used as a substrate may be configured by one film (single layer) as explained above or a multilayer structure (multilayer), wherein same kinds of polyolefin films or different kinds of polyolefin films (for example, a polypropylene film and a polyethylene film) are put together.

A thickness of the substrate (an entire thickness when the substrate has a multilayer structure) is preferably 30 to 300 μm and more preferably 50 to 150 μm. When it is 30 μm or thicker, being cut fully by a short-wavelength laser can be prevented more properly. Also, when it is 300 μm or thinner, an expanding property (uniform stretchability in all directions) can be maintained and it is possible to prevent affecting on optical characteristics specified in the present invention. When the thickness of the substrate is in a range of 30 to 300 μm, it is relatively easy to satisfy the total light transmittance and haze specified in the present invention.

As an adhesive layer, an acrylic type pressure sensitive adhesive agent, rubber type pressure sensitive adhesive agent and other pressure sensitive adhesive agents, hot melt adhesive agent and other adhesive agents, thermal compressible thermoplastic resin films, etc. may be used. An adhesive agent, which exhibits pressure sensitive adhesiveness at a normal temperature and exhibits declined adhesiveness by crosslinking and curing when heated or irradiated with ionizing radiation, etc., is preferable for being excellent in fixing a subject to be adhered to in the step (dicing, etc.) and for being easy to remove the subject from the auxiliary sheet for dicing after the step completes.

Also, the adhesive layer may contain organic resin particles or inorganic particles for satisfying the total light transmittance and haze specified in the present invention. As those organic resin particles and inorganic particles, same ones as those mentioned in the polyolefin film above may be used. Note that when the pigment component as above is contained in the adhesive layer, by suppressing a content thereof to approximately 10 parts by weight or less with respect to 100 parts by weight of adhesive component (adhesive agent) of the adhesive layer, it becomes relatively easy to satisfy the total light transmittance and haze specified in the present invention.

A thickness of the adhesive layer is preferably 3 to 50 μm and more preferably 5 to 30 μm. When it is 3 μm or thicker, preferable adhesive force can be maintained as an auxiliary sheet. While when it is 50 μm or thinner, an expanding property can be maintained properly. When the thickness of the adhesive layer is in a range of 5 to 30 μm, it becomes relatively easy to satisfy the total light transmittance and haze specified in the present invention.

Also, the adhesive layer may be also added with a other additives, such as a leveling agent.

To form the adhesive layer as explained above, a method of preparing an application liquid by arbitrarily adding additives and a diluting solvent as needed to materials composing the adhesive layer, applying the application liquid by a conventionally well-known coating method and drying; and a method of melting resin components composing the adhesive layer, adding other necessary components (inorganic pigment, etc.) to be included therein and making a sheet from the resultant; etc. may be mentioned.

According to the auxiliary sheet for laser dicing of the present invention, since it comprises a substrate and an adhesive layer provided on one surface of the substrate, wherein the substrate is formed of a polyolefin film, total light transmittance is 50% or higher in a wavelength range of 300 to 400 nm, and haze is 70% or higher in a wavelength range of 300 to 400 nm, it is preferably used even in short-wavelength laser processing used on highly hard substrates as it is not cut fully.

The auxiliary sheet for laser dicing of the present invention is used in a manufacture process of semiconductor chips, for example, as below. Namely, the auxiliary sheet for laser dicing of the present invention is adhered to the opposite surface from a surface with semiconductor wafer circuits formed, a laser light is irradiated from the surface with semiconductor wafer circuits, and dividing the semiconductor wafer into individual pieces, one circuit on each piece, so as to manufacture semiconductor chips.

As semiconductor wafers to be applied to the present invention, those having high hardness can be mentioned.

Formation of circuits on the wafer surface is performed by a conventionally well-known method, such as an etching method, lift-off method. The circuits are formed to be a lattice shape on the surface on an inner circumferential portion of the wafer, and there remains an extra portion with no circuit on a range several nm from the outer circumferential edge. A thickness of the wafer before grinding is not particularly limited, but it is normally 500 to 1000 μm or so.

When performing grinding processing on a backside of the semiconductor wafer, a surface protection sheet may be adhered to the circuit surface side to protect the circuits on the surface. The backside grinding processing is to fix the circuit surface side of the wafer with a chuck table, etc. and to grind with a grinder the backside having no circuit formed. When grinding the backside, after grinding the entire backside surface to a predetermined thickness first, only an inner circumferential portion on the backside corresponding to a circuit formation portion (inner circumferential portion) on the surface is ground, and a backside region corresponding to the extra portion, on which circuits are not formed, is left without being ground. As a result, on the semiconductor wafer after grinding, only the inner circumferential portion on the backside is ground to be furthermore thinner and a ring-shaped raised portion is left on the outer circumferential portion. The backside grinding method as above may be performed by a conventionally well-known method. After the backside grinding process, processing of removing a fractured layer generated by grinding may be performed.

Subsequently to the backside grinding step, in accordance with need, etching processing and other processing involving heating, deposition of a metal film on the backside, baking of an organic film or other processing performed at a high temperature may be performed on the backside. Note that when performing processing at a high temperature, the processing on the backside is performed after removing the surface protection sheet.

After the backside grinding step, the auxiliary sheet for laser dicing of the present invention is adhered to the opposite surface side from the surface with circuits on the wafer, and dicing of the wafer is performed. The auxiliary sheet for laser dicing is adhered to the wafer generally by a device called mounter, however, it is not particularly limited to that.

Next, a laser light is irradiated from the semiconductor wafer side of the auxiliary sheet for laser dicing so as to dice the wafer. In the present invention, a short-wavelength laser light having high energy density is used to fully cut a semiconductor wafer having high hardness. As such a short-wavelength laser, for example, a third harmonic (wavelength of 355 nm) of a Nd-YAG laser is preferably used. Intensity and illuminance of a laser light may be at a level capable of cutting the wafer fully while it depends on a thickness of the wafer to be cut.

The short-wavelength laser light explained above is irradiated to streets between circuits so as to make chips, one circuit on each chip, out of the wafer. The number of times that the laser light scans one street may be once or more. Preferably, an irradiating position of the laser light and positions of streets between circuits are monitored and the laser light is irradiated while adjusting a position of the laser light.

By using the auxiliary sheet for laser dicing of the present invention having specific optical characteristics, holding a semiconductor wafer from the opposite surface from that with circuits formed thereon, and irradiating a laser light from the circuit surface side of the semiconductor wafer to perform dicing, the semiconductor wafer can be cut fully without cutting the auxiliary sheet for laser dicing fully, so that semiconductor chips can be produced with high workability.

After the dicing finishes, semiconductor chips are picked up from the auxiliary sheet for laser dicing. The pick-up method is not particularly limited and various conventional well-known methods can be used. For example, a method of pushing individual semiconductor chip upward with a needle from the side of the auxiliary sheet for laser dicing and picking up the pushed-up semiconductor chips by using a pick-up device, etc. may be mentioned. Note that when an adhesive layer of the auxiliary sheet for laser dicing is formed of an ultraviolet ray curing adhesive agent, prior to picking up, the adhesive force is lowered by irradiating an ultraviolet ray and, then, the chips are picked up.

The picked up semiconductor chips are subjected to die bonding and resin sealing in normal methods, so that semiconductor devices are produced.

An explanation was made above on an example of using a semiconductor wafer as an adherend, however, the auxiliary sheet for dicing of the present invention is not limited to that and can be also used for dicing semiconductor packages, optical device wafers using sapphire substrates and substrates formed by depositing silver on copper, etc., glass substrates, ceramic substrates, organic material substrates of FPC, etc. and metal materials of elaborate instruments, etc.

### EXAMPLES

Below, the present invention will be explained further in detail with examples. Note that “part” and “%” are based on weight unless otherwise mentioned.

### 1. Production of Auxiliary Sheet for Laser Dicing

### Example 1

On one surface of a polyethylene film having a thickness of 100 μm as a substrate, an adhesive layer application liquid prepared from the formula below was applied by a bar coating method and dried to obtain a thickness of 23 μm after drying, and an adhesive layer was formed. As a result, an auxiliary sheet for laser dicing of the example 1 was obtained.

< Adhesive Layer Application Liquid in Example 1 >

| | | |
|---|---|---|
| acrylic type pressure sensitive adhesive agent | 100 | parts |
| (COPONYL N4823 by Nippon Synthetic Chemical Industry | | |
| Co., Ltd.) | | |
| isocianate compound | 0.44 | part |
| (CORONATE L45E by Nippon Polyurethane Industry Co., | | |
| Ltd.) | | |
| diluting solvent | 54 | parts |

### Example 2

Other than using a polyethylene film having a thickness of 110 μm as the substrate, an adhesive layer was formed under the same condition as that in the example 1, and an auxiliary sheet for laser dicing of an example 2 was obtained.

### Example 3

Other than changing the adhesive layer application liquid in the example 1 to that prepared from the formula below and designing to obtain a thickness of 22 μm after drying, an auxiliary sheet for laser dicing of an example 3 was obtained in the same way as in the example 1.

< Adhesive Layer Application Liquid in Example 3 >

| | | |
|---|---|---|
| acrylic type pressure sensitive, adhesive agent | 100 | parts |
| (COPONYL N4823 by Nippon Synthetic Chemical Industry | | |
| Co., Ltd.) | | |
| isocianate compound | 0.44 | part |
| (CORONATE L45E by Nippon Polyurethane Industry | | |
| Co., Ltd.) | | |
| silicon resin particles | 4 | parts |
| (Tospearl 120 by Momentive Performance Materials Inc.) | | |
| diluting solvent | 63 | parts |

### Example 4

Other than changing the adhesive layer application liquid in the example 1 to that prepared from the formula below and designing to obtain a thickness of 26 μm after drying, an auxiliary sheet for laser dicing of an example 4 was obtained in the same way as in the example 1.

< Adhesive Layer Application Liquid in Example 4 >

| | | |
|---|---|---|
| acrylic type pressure sensitive adhesive agent | 100 | parts |
| (COPONYL N4823 by Nippon Synthetic Chemical Industry | | |
| Co., Ltd.) | | |
| isocianate compound | 0.44 | part |
| (CORONATE L45E by Nippon Polyurethane Industry | | |
| Co., Ltd.) | | |
| zirconium oxide | 4 | parts |
| (PCS by Nippon Denko Co., Ltd.) | | |
| diluting solvent | 63 | parts |

### Example 5

Other than changing the adhesive layer application liquid in the example 1 to that prepared from the formula below, an auxiliary sheet for laser dicing of an example 5 was obtained in the same way as in the example 1.

< Adhesive Layer Application Liquid in Example 5 >

| | | |
|---|---|---|
| acrylic type pressure sensitive adhesive agent | 100 | parts |
| (COPONYL N4823 by Nippon Synthetic Chemical Industry | | |
| Co., Ltd.) | | |
| isocianate compound | 0.44 | part |
| (CORONATE L45E by Nippon Polyurethane Industry | | |
| Co., Ltd.) | | |
| calcium carbonate | 3.27 | parts |
| (SUN LIGHT SL700 by Takehara Kagaku Kogyo | | |
| Co., Ltd.) | | |
| colloidal silica | 0.24 | part |
| (AEROSIL R972 by Nippon Aerosil Co., Ltd.) | | |
| titanium oxide | 0.48 | part |
| (MULTI-RACK W106 by Toyo Ink MFG Co., Ltd.) | | |
| diluting solvent | 63 | parts |

### Example 6

Other than changing to 20 parts of silicon resin particles and 100 parts of diluting solvent, same adhesive layer application liquid as that in the example 3 was prepared. This application liquid was applied to one surface of a substrate, a polypropylene film having a thickness of 100 μm, by a bar coating method and dried so as to obtain a thickness of 22 μm after drying, and an adhesive layer was formed. As a result, an auxiliary sheet for laser dicing of an example 6 was obtained.

### Comparative Example 1

Other than changing to 16.36 parts of calcium carbonate, 1.21 parts of colloidal silica, 2.42 parts of titanium oxide and 173 parts of diluting solvent, same adhesive layer application liquid as that in the example 5 was prepared. This application liquid was applied to one surface of a substrate, same polypropylene film as that in the example 6, by a bar coating method and dried so as to obtain a thickness of 25 μm after drying, and an adhesive layer was formed. As a result, an auxiliary sheet for laser dicing of a comparative example 1 was obtained.

### Comparative Example 2

Other than changing to 20 parts of zirconium oxide and 55 parts of diluting solvent, same adhesive layer application liquid as that in the example 4 was prepared. This application liquid was applied to one surface of a substrate, same polypropylene film as that in the example 6, by a bar coating method and dried so as to obtain a thickness of 23 μm after drying, and an adhesive layer was formed. As a result, an auxiliary sheet for laser dicing of a comparative example 2 was obtained.

### Comparative Example 3

Other than using COPONYL N3527 (Nippon Synthetic Chemical Industry Co., Ltd.) as an acrylic type pressure sensitive adhesive agent, same adhesive layer application liquid as that in the example 4 was prepared. This application liquid was applied to one surface of a substrate, a polypropylene film having a thickness of 90 μm, by a bar coating method and dried so as to obtain a thickness of 23 μm after drying, and an adhesive layer was formed. As a result, an auxiliary sheet for laser dicing of a comparative example 3 was obtained.

### 2. Evaluation

### (1) Total Light Transmittance

As to the auxiliary sheets for laser dicing of the examples 1 to 6 and the comparative examples 1 to 3, total light transmittance (JIS J7375: 2008) was measured in a wavelength range of 300 to 400 nm at an interval of 1 nm by using a spectral photometer (UV-3101PC: Shimazu Corporation), and an average value thereof was obtained. When measuring, a light was irradiated from the adhesive layer side. The results are shown in Table 1.

### (2) Haze Value

As to the auxiliary sheets for laser dicing in the examples 1 to 6 and comparative examples 1 to 3, a diffused light transmittance was measured in a wavelength range of 300 to 400 nm at an interval of 1 nm by using a spectral photometer (UV-3101PC: Shimazu Corporation). When measuring, a light was irradiated from the adhesive layer side. Next, the total light transmittance at an interval of 1 nm in a wavelength range of 300 to 400 nm measured in (1) above and the diffused light transmittance were substituted into the haze calculation formula below to obtain haze values, and an average value thereof was obtained. The calculation results are shown in Table 1.

Haze (%)=(diffused light transmittance/total light transmittance)×100

### (3) Cutting Suitability

Based on the laser irradiation condition below, the auxiliary sheets for laser dicing in the examples 1 to 6 and comparative examples 1 to 3 were irradiated with a laser light from the adhesive layer side of the auxiliary sheets by using a Nd-YAG laser. The results are indicated by “Excellent” for those which cut the substrate by only less than 50 μm, “Good” for those which cut the substrate by 50 μm or more but less than 80 μm, “Acceptable” for those which cut the substrate by 80 μm or more but did not cut fully, and “Poor” for those which cut the substrate fully. The results are shown in Table 1.

### <Laser Irradiation Condition>

wavelength: 355 nm

repetition frequency: 100 kHz

average power: 5w

irradiation times: 4 times/1 line

pulse width: 50 ns

converging point: ellipse (long axis of 100 μm and short axis of 10 μm)

processing feed rate: 100 mm/sec.

TABLE 1

| | Total Light | | |
|---|---|---|---|
| | Transmittance | | Cutting |
| | (%) | Haze (%) | Suitability |
| Example 1 | 85.5 | 82.1 | Excellent |
| Example 2 | 88.0 | 87.4 | Excellent |
| Example 3 | 71.5 | 91.3 | Excellent |
| Example 4 | 53.3 | 84.7 | Good |
| Example 5 | 55.3 | 88.6 | Good |
| Example 6 | 69.0 | 94.5 | Acceptable |
| Comparative | 10.9 | 97.2 | Poor |
| Example 1 | | | |
| Comparative | 25.3 | 98.5 | Poor |
| Example 2 | | | |
| Comparative | 84.5 | 18.8 | Poor |
| Example 3 | | | |

From the results above, the auxiliary sheets for laser dicing in the examples 1 to 6 comprise a substrate formed of a polyolefin film and an adhesive layer provided on one surface of the substrate, wherein the total light transmittance was 50% or higher in the wavelength range of 300 to 400 nm, and the haze was 70% or higher in the wavelength range of 300 to 400 nm, consequently, they were not cut fully even when using a short-wavelength laser. Accordingly, according to the auxiliary sheet for laser dicing in the examples 1 to 6, it is known that they are not cut fully even in a dicing step of a semiconductor wafer using a short-wavelength laser and do not deteriorate the workability.

Particularly, since the auxiliary sheets for laser dicing in the examples 1 to 3 exhibited total light transmittance of 70% or higher in the wavelength range of 300 to 400 nm and haze of 80% or higher in the wavelength range of 300 to 400 nm, the auxiliary sheets for laser dicing had a less chance of being cut and had excellent endurance.

Also, since the auxiliary sheets for laser dicing in the examples 1 to 5 use a polyethylene film as a substrate, they had a less chance of being cut even in a dicing step using a short-wavelength laser and had excellent endurance.

On the other hand, since the auxiliary sheets for laser dicing in the comparative examples 1 and 2 exhibited total light transmittance of lower than 50% in the wavelength range of 300 to 400 nm, the short-wavelength laser stayed inside the auxiliary sheets for laser dicing and all of them were cut fully. The auxiliary sheet for laser dicing in the comparative example 3 exhibited total light transmittance of 50% or higher in the wavelength range of 300 to 400 nm, however, haze was lower than 70% in the wavelength range of 300 to 400 nm. Therefore, when the short-wavelength laser was irradiated on the auxiliary sheet for laser dicing, the light was not be able to be diffused and it was cut fully. Accordingly, according to the auxiliary sheets for laser dicing in the comparative examples 1 to 3, it is known that they result in being poor in workability of collecting semiconductor chips in a dicing step of the semiconductor wafer using a short-wavelength laser.

Next, when irradiating an ultraviolet ray at an irradiance level of 400 mj/cm² from the substrate side of the auxiliary sheet for laser dicing of the example 1, an adhesive force of 20N/25 mm before the ultraviolet ray irradiation became 0.6N/25 mm after the irradiation, which means the adhesive force declined. Accordingly, it is known that when the auxiliary sheet for laser dicing of the present invention is used in a dicing step, it becomes easy to remove from an adherend and good workability can be obtained.

1. An auxiliary sheet for laser dicing, characterized by comprising a substrate and an adhesive layer provided on one surface of the substrate, wherein:
the substrate is formed of a polyolefin film;
total light transmittance is 50% or higher in a wavelength range of 300 to 400 nm; and
haze is 70% or higher in a wavelength range of 300 to 400 nm.

2. The auxiliary sheet for laser dicing according to claim 1, characterized in that
the substrate is formed of a single layer of a polypropylene film or a polyethylene film, a plurality of layers of polypropylene films or polyethylene films, or a plurality of layers of a polypropylene film and a polyethylene film.

3. The auxiliary sheet for laser dicing according to claim 1, characterized in that
the adhesive layer includes an adhesive agent which exhibits pressure sensitive adhesiveness at a normal temperature and exhibits declined adhesiveness as a result of cross-linking and curing by being heated or irradiated with ionizing radiation.

4. The auxiliary sheet for laser dicing according to claim 1, characterized in that
the haze is 80% or higher in a wavelength range of 300 to 400 nm.

5. The auxiliary sheet for laser dicing according to claim 1, characterized in that
the total light transmittance is 70% or higher in a wavelength range of 300 to 400 nm.

6. The auxiliary sheet for laser dicing according to claim 1, characterized in that
a thickness of the substrate is 30 to 300 μm.

7. The auxiliary sheet for laser dicing according to claim 3, characterized in that
a thickness of the adhesive layer is 3 to 50 μm.

8. The auxiliary sheet for laser dicing according to claim 3, characterized in that
the adhesive layer includes organic resin particles or/and inorganic particles as a pigment component.

9. The auxiliary sheet for laser dicing according to claim 8, characterized in that
the pigment component is included in a content of 10 parts by weight or less with respect to 100 parts by weight of the adhesive agent.

10. The auxiliary sheet for laser dicing according to claim 1, characterized in that
a thickness of the adhesive layer is 3 to 50 μm.

11. The auxiliary sheet for laser dicing according to claim 1, characterized in that
the adhesive layer contains organic resin particles or/and inorganic particles as a pigment component.

12. The auxiliary sheet for laser dicing according to claim 11, characterized in that
the pigment component is included in a content of 10 parts by weight or less with respect to 100 parts by weight of an adhesive component of the adhesive layer.
